(19) United States
(12) Patent Application Publication
(10) Pub. No.: US 2024/0210837 A1
(43) Pub. Date: Jun. 27, 2024

(54) DIGITAL ULTRAVIOLET LITHOGRAPHY METHOD AND APPARATUS

(71) Applicant: The Hong Kong Polytechnic University, Hung Hom (HK)

(72) Inventors: Aping ZHANG, Hung Hom (HK); Zuoqin DING, Hung Hom (HK); Han WANG, Hung Hom (HK); Taige LI, Hung Hom (HK)

(73) Assignee: The Hong Kong Polytechnic University, Hung Hom (HK)

(21) Appl. No.: 18/087,443

(22) Filed: Dec. 22, 2022

(51) Int. Cl. G03F 7/20

(52) U.S. Cl. CPC G03F 7/705; G03F 7/70283; G03F 7/70441

(57) ABSTRACT

An algorithm-driven digital ultraviolet (UV) lithography (DUL) method and apparatus used to fabricate high-quality optical waveguide and many other kinds of high-resolution microstructures without the use of a photomask. Instead of the use of an actual photomask, a virtual mask based on a spatial light modulator is used. The DUL method and apparatus can compensate for a proximity effect caused by light scattering and make the exposure adaptive to a nonlinear response curve of a photoresist, in which an exposure dose-map is created based on the bitmap of a designed pattern together with the optimization parameters determined by system configuration and the photoresist. To fabricate large-area patterns, a plurality of sliced exposure dose-submaps with transition zones that can depress the stitching error caused by mechanical mispositioning are generated for digital lithographic exposure process.

### BACKGROUND OF THE INVENTION

### 1. Field of the Invention

An aspect of this application relates to an algorithm-driven digital ultraviolet lithography (DUL) technology and its apparatus that can rapidly fabricate high-quality low-loss optical waveguides without the need for a photomask.

### 2. Description of the Related Art

Traditional photolithography has been the mainstay for the production of semiconductor and photonic chips for about 60 years. Traditional photolithography relies on the use of a photomask, through which ultraviolet light transfers patterns on to a wafer's photoresist in a process that is costly and time-consuming to deploy. In addition to a long lead time, a photomask can cost upwards of US$1 million.

Many maskless lithography technologies have been developed to emancipate the manufacturing of chips from a photomask. The most widely used form of maskless lithography is electronic beam lithography (EBL). However, the fabrication speed of conventional single-beam EBL is very low, and Coulomb repulsion makes parallel operation of multiple electronic beams difficult. Therefore, optical maskless lithography has become one of the most promising technologies for next-generation lithography.

Another popular optical maskless lithography technology is scanning mirror-based direct laser writing. However, its fabrication capacity is still low because of its single-spot scanning nature. A very promising optical maskless lithography technology is based on a spatial light modulator (SLM), such as a digital micromirror device (DMD), which can harness millions of pixels to create light patterns for rapid patterning processes.

Although various forms of SLM- or DMD-based optical maskless lithography technology have been demonstrated, very few of them can be applied to fabricate high-quality photonic chips. Not only is a technology needed to achieve a precision optical patterning with a resolution below 2 μm, but also methods are needed to create large-area photonic chips with very long optical waveguides with ultra-smooth sidewalls.

### SUMMARY OF THE INVENTION

According to an aspect of the application, a new kind of lithography technology has been developed that can be used to fabricate high-quality photonic chips and many other kinds of high-resolution microstructures.

According to an aspect of the application, algorithm(s) and apparatus to achieve all-digital high-resolution lithography technology for high-quality optical waveguide fabrication have been developed.

According to an aspect of the application, a digital ultraviolet (UV) lithography (DUL) technology has been developed to rapidly fabricate high-quality optical waveguide, which is an essential element of photonic chips, without the use of a photomask.

According to an aspect of the application, the DUL process uses a grayscale optical exposure to compensate for a proximity effect caused by the scattering of light on a substrate. The compensation method is developed by introducing an exposure dose-map built with a Gaussian distribution assumption of scattered light pixels.

According to an aspect of the application, the exposure dose-map can be further corrected to make each pixel of the dose-map adaptive to the response curve of different photoresists. A threshold parameter of exposure time is used in this correction process.

According to an aspect of the application, the exposure dose-map of a large pattern is sliced into a large number of exposure dose-submaps (submaps), and the submaps are stitched seamlessly by introducing transition regions between submaps. An exposure-dose slope with nonlinear compensation, which is done in quadratic form, for a photoresist has been developed to create transition regions for minimizing stitching imperfection between two adjacent sub-patterns. Transition zones are made as the DUL process does not use continuous scanning, and mechanical mispositioning may inevitably appear when the substrate is moved from one position to the next by a motorized stage for exposure of different submaps.

According to an aspect of the application, the pattern is reduced by projection optics. This allows for the elimination of a microlens array and sharing of an objective lens with a digital camera-based machine vision module.

According to an aspect of the application, the digital camera (for, example a charge coupled device (CCD) or complementary metal-oxide semiconductor (CMOS)) is used to precisely check the tilt of a substrate, where the Z positions of 3 or 4 points of the substrate are checked with a machine vision module and used to calculate the levelness of the substrate. By doing this, the distance between the objective lens and the substrate is continuously calculated by using the information obtained by pre-checking of substrate and adjusted before exposure of each submap.

According to an aspect of the application, a closed-loop exposure scheme is established in which the digital camera continuously checks the substrate and photoresist before and during exposure.

According to an aspect of the present invention, a method of performing digital lithography for a maskless optical exposure process, comprises: converting a computer aided design (CAD) pattern into a bitmap; and transforming the bitmap to an exposure dose-map for (1) compensation of a proximity effect and (2) adaptive to a non-linear response curve of a photoresist, and slicing the exposure dose-map into a plurality of submaps with transition zones around a boundary between two adjacent submaps so as to depress a stitching error caused by mechanical mispositioning when the substrate is moved from one position to the next by a motorized stage.

According to an aspect of the present invention, a digital ultraviolet lithography (DUL) apparatus comprises: a spatial light modulator comprising a plurality of pixels used as a virtual mask; a processor configured to: convert a computer aided design (CAD) pattern into a bitmap; transform the bitmap to an exposure dose-map for (1) compensation of a proximity effect and (2) adaptive to a non-linear response curve of a photoresist, and divide the exposure dose-map into a plurality of submaps with transition zones around a boundary between two adjacent submaps so as to depress a stitching error caused by mechanical mispositioning, wherein the spatial light modulator is configured to generate a light pattern to expose the photoresist on a substrate using the plurality of submaps one by one.

According to an aspect of the present invention, a computer-readable storage medium, comprises a computer program, wherein when the computer program is run on a computer, the computer is enabled to perform a method comprising: converting a computer aided design (CAD) pattern into a bitmap; and transforming the bitmap to an exposure dose-map for (1) compensation of a proximity effect and (2) adaptive to a non-linear response curve of a photoresist, and slicing the exposure dose-map into a plurality of submaps with transition zones around a boundary between two adjacent submaps so as to depress a stitching error caused by mechanical mispositioning when the substrate is moved from one position to the next by a motorized stage.

Additional aspects and/or advantages of the invention will be set forth in part in the description which follows and, in part, will be obvious from the description, or may be learned by practice of the invention.

### BRIEF DESCRIPTION OF THE DRAWINGS

These and/or other aspects and advantages of the invention will become apparent and more readily appreciated from the following description of the embodiments, taken in conjunction with the accompanying drawings of which:

FIG. 1 is a schematic diagram of a digital UV lithography exposure (DUL) apparatus according to an aspect of the present application;

FIG. 2 is a schematic diagram of a computing device shown in FIG. 1;

FIG. 3 is a flowchart and schematic of a method of preparing pattern data for a digital lithographic exposure process according to an embodiment of the present invention;

FIG. 4 is a flowchart of lithographic exposure processes according to an embodiment of the present invention;

FIG. 5 is a schematic diagram of the stitching of sliced exposure dose-submaps with transition zones for fabrication of a large-area pattern;

FIG. 6A is a schematic diagram of a photoresist (here is SU-8) spin-coated upon a substrate and a schematic of an SU-8 optical waveguide according to an embodiment of the present invention, and

FIG. 6B shows simulated mode profiles, which indicate fundamental transverse electric (TE₀) and transverse magnetic (TM₀) modes of the SU-8 optical waveguide;

FIG. 7A shows an example of a bitmap and a converted exposure dose-map of a line pattern (as a short section of a designed optical waveguide).

FIG. 7C shows another line pattern with a half-maximum gray edge.

FIGS. 7B and 7D show scanning electron microscopy (SEM) images of fabricated line patterns when the total exposure time t_{T}, the threshold time t₀ and the FWHM w are 18 s, 1.8 s, and 3.0, respectively.

FIG. 7E and FIG. 7F shows the effects of different full width at half maximum (FWHM) w on exposure dose-maps and the fabricated patterns, respectively;

FIGS. 8A and 8B show grayscale images of a transition zone of the exposure dose-submaps when the compensation coefficients are 0.1 and −0.1, respectively.

FIG. 8C shows the measured transmission spectra of fabricated waveguides with the compensation coefficients of −0.15, −0.1, −0.05, 0, and 0.05.

FIGS. 8D-8H show SEM images of their corresponding stitched transition zone, respectively;

FIGS. 9A and 9B show two examples of fabricated bend waveguides with the radii of 75 μm and 100 μm, respectively.

FIG. 9C shows the measured transmission spectra of bend waveguides with the radii of 75 μm, 100 μm, 125 μm, 150 μm, and 175 μm.

FIG. 9D shows a normalized bending loss of each 90°-arc waveguide section at the wavelength of 1550 nm;

FIGS. 10A and 10B are scanning electron microscope (SEM) images of fabricated spiral waveguides with different lengths.

FIGS. 10C and 10D are the enlarged images at different positions,

FIG. 10E shows the measured transmission spectra of waveguides with the lengths of 8.1 mm, 13.1 mm, 20.8 mm, and 23.9 mm, respectively,

FIG. 10F shows the measured losses at the wavelength of 1550 nm, which was extracted from FIG. 10E;

FIG. 11A shows an SEM image of a fabricated MMI coupler.

FIG. 11B shows the measured normalized transmission spectra from its two output ports;

FIG. 12A is the SEM image of a fabricated 1×2 Y-branch power splitter, which has one access waveguide and two branching waveguides with S-bends, and

FIG. 12B shows measured normalized transmission spectra of the Y-branch power splitter; and

FIG. 13A shows an MRR with a gapless coupling section.

FIG. 13B shows the measured transmission spectrum of the MRR at a wavelength ranging from 1520 nm to 1610 nm,

FIGS. 13C and 13D are close-ups of the spectra at the wavelengths near 1551 nm and 1600 nm, respectively.

### DETAILED DESCRIPTION OF THE EMBODIMENTS

Reference will now be made in detail to the present embodiments of the present invention, examples of which are illustrated in the accompanying drawings, wherein like reference numerals refer to the like elements throughout. The embodiments are described below in order to explain the present invention by referring to the figures.

The following embodiments, description and drawings are illustrative of the invention and are not to be construed as limiting the invention. Numerous specific details are described to provide a thorough understanding of various embodiments of the present invention. However, in certain instances, well-known or conventional details are not described in order to provide a concise discussion of embodiments of the present invention. Reference in the specification to “one embodiment” or “an embodiment” or “another embodiment” means that a particular feature, structure, or characteristic described in conjunction with the embodiment can be included in at least one embodiment of the invention. The appearances of the phrase “in one embodiment” in various places in the specification do not all necessarily refer to the same embodiment. With the advantages of low cost, easy fabrication and high transmission, polymer-based optical waveguides have been extensively studied and applied in various fields, such as photonic integrated devices and optical label-free biosensors. In the applications of integrated devices, polymer waveguides show excellent flexibility in a vertical direction, which provides great promise in vertical effective refractive index (RI) modulation and 2.5d or 3d structure development, such as maxwell fisheye-based multimode crossings. In addition, due to their good compatibility with different substrates and materials, polymer waveguides are attractive for hybrid integration of photonic devices or chips with different functional materials. In applications relating to label-free biosensors, polymer waveguides can directly absorb proteins on their surfaces and immobilize them by covalent bond, and thus, bimolecular information can be easily detected by combining them with optical waveguide structures. Optical waveguides can be made by using different materials, such as polymer, silicon or silica etc. For ease of demonstration, we use polymer optical waveguides as the example to demonstration the fabrication ability of the technology. It can also be applied to fabricate other kinds of optical waveguides, in case that we have the etching facility to further transfer the pattern to other material platform.

In addition to the fabrication of optical waveguides, the technology can also be applied to fabricate optical microcavities, optical/electrical sensors, interdigital electrodes and flexible electronics, microfluidic devices, photomasks, and other devices.

Various fabrication technologies and methods have been utilized to fabricate polymer waveguides, including optical lithography, laser direct writing, and E-beam lithography. Traditional optical lithography provides an efficient way for rapid fabrication of polymer waveguides. However, traditional optical lithography lacks flexibility in the fabrication of gray-scale features, e.g., vertical integration. Laser direct writing or e-beam lithography technologies have good flexibility but are commonly less efficient because of their inherent single-spot scanning nature. These bottleneck problems can be overcome by using digital ultraviolet lithography (DUL).

DUL technology uses a high-speed spatial light modulator, such as a digital micro-mirror device (DMD), with millions of pixels as a virtual dynamic mask, which renders great promise in the all-digital high-throughput fabrication of polymer waveguides with complicated geometry. The DMD has millions of micro-mirrors that can be tilted to represent “ON” and “OFF” states. In the “ON” state, light is reflected by the micro-mirrors and forms an optical pattern of a very large number of pixels on a substrate after passing through an optical projection system. In the “OFF” state, light is directed elsewhere and the corresponding pixels appear dark. The state of each micro-mirror can be rapidly controlled by a computer with image data of a designed model. Such a digital light processing nature enables its ability for grayscale exposure and 3D microfabrication.

To fabricate polymer waveguides under single-mode operation, the resolution of a DUL apparatus should be below 2 μm, for example. To achieve this goal, many efforts have been made to improve the resolution of DMD-based lithography technology.

According to an aspect of the application, a method of fabrication of high-quality polymer optical waveguides uses a high-resolution DUL apparatus based on high-magnification reduction projection optics and a small-pixel-size DMD, the pixel size being 7.6 μm, for example. The pixel size of DMD may range from 13.7 μm to 7.6 μm, possibly other ranges. Other pixels sizes may be utilized as well. In particular, proximity effects are corrected by an exposure dose-map calculated with the approximation of a Gaussian-like scattered light pixel. Stitching loss is depressed by creation of a transition zone with a nonlinear compensation in quadratic form. Based on experiments, multiple optical waveguides, made of SU-8 by way of just one example, such as a multimode interference (MMI) splitter, a Y-branch power splitter and micro-ring resonators (MRR) are fabricated and demonstrate the performance of a high-resolution DUL apparatus. It is contemplated that other types of optical waveguides may be implemented according to embodiments of the present invention. Examples of other types include lithium niobate, silicon or silica optical waveguides.

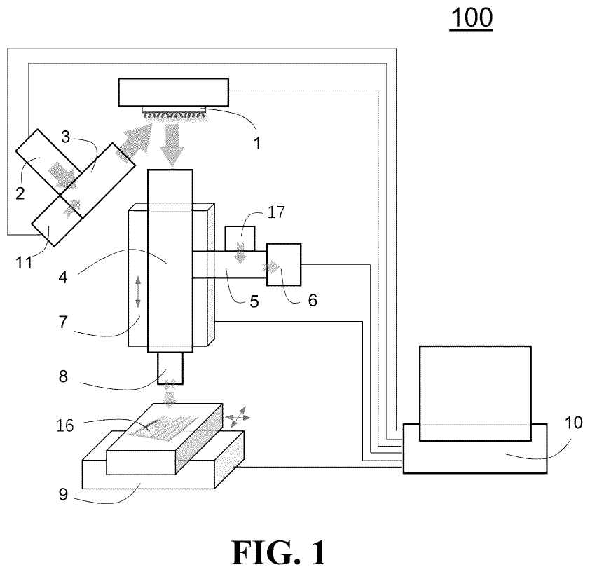

FIG. 1 is a schematic diagram of a digital UV lithography exposure (DUL) apparatus 100 according to an aspect of the present application. The digital UV lithography device 100 includes a spatial light modulator 1; a UV source 2; a UV beam homogenizer 3; projection optics 4; imaging optics 5; a digital camera 6; a motorized vertical stage 7; an objective lens 8; a motorized XY stage 9 on which a substrate 16 is placed; a computing device with large memory and communication interfaces 10; and visible light sources 11 & 17.

The digital UV lithography exposure apparatus 100 is used in the fabrication of designed waveguides. The motorized XY stage 9 is a nano-precision motorized stage. The projection optics 4 reduces the pitch of light pixels to ˜300 nm. A range of the pitch could be: 180 nm to 2 μm. The digital camera 6 is integrated to inspect substrate and monitor the photoresist during exposure process. The visible light sources 11 and 17 provide light illumination for the digital camera 6.

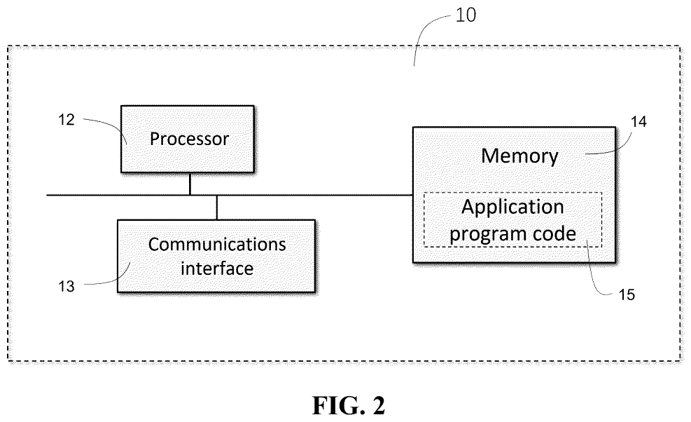

FIG. 2 is a schematic diagram of the computing device 10 shown in FIG. 1. according to an embodiment of the present invention. As shown in FIG. 2, the computing device 10 includes at least one processor 12, a memory 14, and at least one communications interface 13. The processor 12, the memory 14, and the communications interface 13 are connected and communicate with each other through a communications bus.

The processor 12 may be a general-purpose central processing unit (CPU), implemented by at least one of electronic units such as an application-specific integrated circuit (ASIC), one or more integrated circuits, a digital signal processor (DSP), a programmable logic device (PLD), a field programmable gate array (FPGA), a processor, a controller, a microcontroller, and/or a microprocessor, or may be implemented by a software module that performs at least one function or operation.

The communications interface 13 is configured to communicate with other elements of the DUL apparatus 100, through a wire and/or wireless connection, and may be configured to communicate with communications networks, such as the Ethernet, a radio access network (RAN), or a wireless local area network (WLAN).

The memory 14 (a non-transitory computer readable medium) may be a read-only memory (ROM) or another type of static storage device that can store static information and an instruction, a random access memory (RAM) or another type of dynamic storage device that can store information and an instruction, or may be an electrically erasable programmable read-only memory (EEPROM), a compact disc read-only memory (CD-ROM) or another compact disc storage, an optical disc storage (including a compact disc, a laser disc, an optical disc, a digital versatile disc, a Blu-ray disc, or the like), a magnetic disk storage medium or another magnetic storage device, or any other medium that can be used to carry or store expected program code in a form of an instruction or a data structure and that can be accessed by a computer. However, the memory 14 is not limited thereto. The memory may exist independently, and is connected to the processor 12 by using a bus. Alternatively, the memory 14 may be integrated with the processor 12.

The memory 14 is configured to store application program code 15 for executing the foregoing and following methods and processes, and the processor 12 controls the execution. The processor 12 is configured to execute the application program code 15 stored in the memory 14.

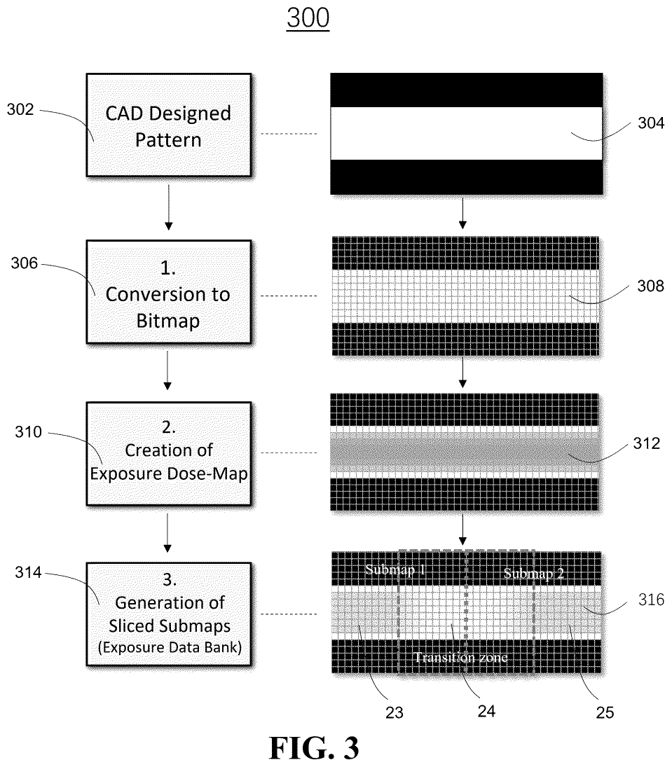

FIG. 3 is a flowchart and schematic of a method 300 of preparing pattern data for a digital lithographic exposure process according to an embodiment of the present invention. The left side of FIG. 3 indicates method operations of the preparation of the pattern data, wherein the right side of FIG. 3 shows an example of how to generate a bitmap and convert the bitmap into an exposure dose-map and slice the exposure dose-map into two exposure dose-submaps with a transition zone for a line pattern. The line pattern is a short section of a “line” (here is the waveguide), which is a simple shape used for explanation of a transformation from a vector graphic design to a bitmap to an exposure dose-map to submaps in exposure-data preparation.

A computer aided designed (CAD) pattern 302 (here, a simple line pattern, is used as an example) for a photonic or microelectronic chip is transformed into a geometric gray-scale bitmap in operation 306.

In operation 310, the geometric gray-scale bitmap is converted into an exposure dose-map. Here, a proximity effect compensation method is built with a Gaussian distribution assumption of scattered light pixels. A nonlinear response curve of a photoresist is also incorporated during the bitmap conversion of the geometric gray-scale bitmap into the exposure dose-map.

In operation 314, to fabricate a large-size pattern, the exposure dose map is divided into submaps with transition zones to generate an exposure data bank, i.e. submap data bank. Nonlinear compensation in quadratic form is applied in the transition zones to make the stitching process adaptive to different photoresists. The transition zones typically have a width of 4-20 pixels, but are not to such.

Graphs 304, 308, 312 and 316 are examples using a simple line pattern to show the transformation from a vector graphic design to a bitmap to an exposure dose-map to exposure dose-submaps given in FIGS. 302, 306, 310 and 314, respectively. The size of the submaps is determined by the pixel numbers of spatial light modulator 1. Currently, it may be in the range of 1-4 million pixels, but that is changeable.

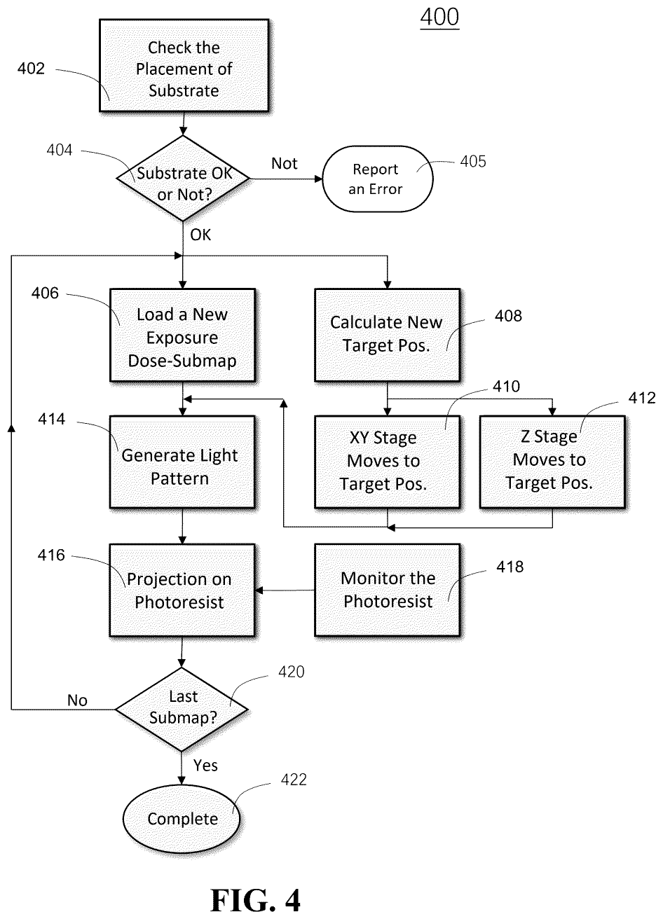

FIG. 4 is a flow chart of a DUL exposure process 400 according to an embodiment of the present invention. The DUL exposure process 400 is performed using the DUL apparatus 100 shown in FIG. 1.

In operation 402, the placement of substrate 16 is checked by a machine vision module. The machine vision module is a collection of algorithms for imaging processing. The digital camera 6 takes images from substrate 16, while the machine vision module is used to extract information from the images. Position information and levelness of the substrate is obtained to determine if the lithographic exposure could be continued in operation 404. If the lithographic exposure cannot be continued, an error of unacceptable levelness or lack of location marks will be reported in operation 405 to the user of the DUL apparatus 100 in one form or another.

Exposure dose-submap data of a sub-pattern is loaded to the spatial light modulator 1 from the computing device 10 for light pattern generation in operation 406.

In operation 408, position information and the levelness of the substrate 48 obtained in operation 402 will be used to calculate new positions of XY and Z stages.

In operation 410, the motorized XY stage 9 moves to its calculated target positions in an X-Y plane, and in operation 412, the motorized vertical (or Z) stage 7 moves to its calculated target position in a Z-axis direction perpendicular to the X-Y plane.

The spatial light modulator 1 generates the light pattern according to the loaded exposure dose-map in operation 414.

In operation 416, UV light in a range of 320-400 nm, which is emitted from the UV source 2, and passed through the UV beam homogenizer 3, is transformed into a light pattern by the spatial light modulator 1. The light pattern will be dynamically projected upon the substrate after passing through the projection optics (relay optics 4 and objective lens 8). The projection process is controlled by the gray-scale values defined by the exposure dose-submap loaded to the DMD.

In operation 418, the machine vision module is used to monitor a dynamic exposure process in real time. For a photoresist made of a photopolymer that can instantly respond to UV exposure, DUL apparatus 100 can also monitor the evolution of the geometric change of the photoresist spin-coated upon the substrate during the exposure process.

In operation 420, the processor 12 of the computer 10 checks whether all of the submaps have been projected, and the lithographic exposure process 400 is completed in operation 422 after the projecting of all of the submaps. If it is determined that the last submap has not been projected in operation 420, the lithographic exposure process 400 returns to loading of a new submap in operation 406 and the calculating of a new target position in operation 408 is performed.

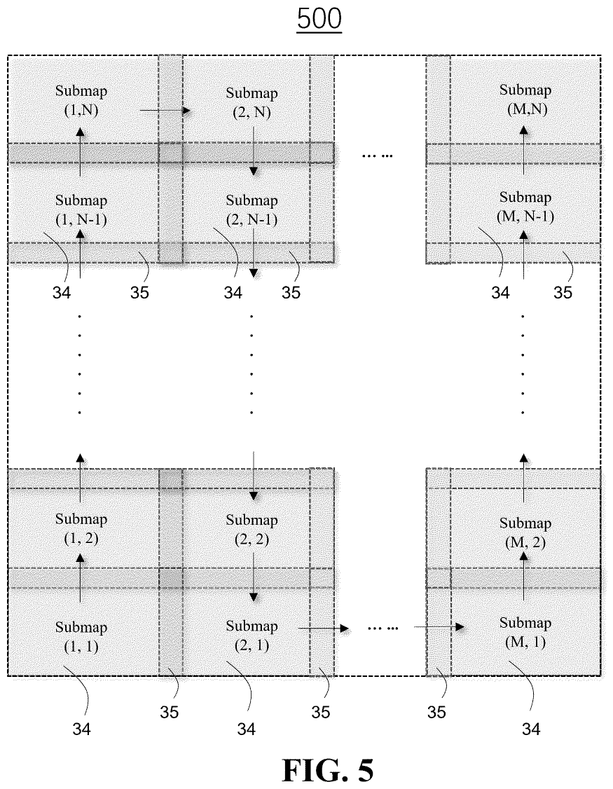

FIG. 5 is a schematic of a seamless stitching process 500 using the submaps with transition zones.

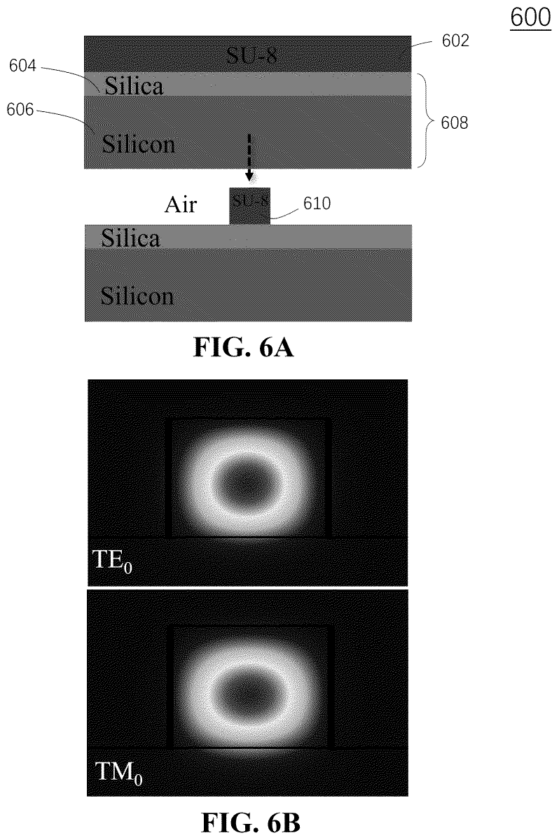

FIG. 6A shows a schematic of the photoresist 602 (here is SU-8) spin-coated upon the substrate 608 and the schematic of an SU-8 waveguide 610 fabricated on the substrate. A ridge waveguide structure with air cladding 602 and a 4-μm thick SiO₂ insulator 604 upon a silicon wafer 606 is used to achieve a high refractive index contrast for strong confinement of light propagating in the SU-8 waveguide with a small bending radius. A finite difference eigenmode (FDE) solver is used to design and analyze the waveguide structure. The size of the SU-8 waveguide in this example is 2.0 μm (H)×2.4 μm (W) so as to make the SU-8 waveguide operate under a single-mode condition with a relatively low polarization dependence. FIG. 6B shows simulated mode profiles, which indicate that only fundamental transverse electric (TE₀) and transverse magnetic (TM₀) modes are supported.

The designed patterns of waveguides are converted into 8-bit grayscale exposure dose-map and uploaded to the spatial light modulator 1 (DMD), which acts as a virtual mask for use in the optical exposure process. With the assumption that a gray value g can be analogically represented by the depth of light penetration in an SU-8 photoresist in exposure process, the exposure time t can be determined in line with the Beer Lambert law as

$$t = {t}_{0} exp ( g / {c}_{r} ) , \qquad ( 1 )$$

where t₀ is the threshold of exposure time, the constant cᵣ depends on the contents of SU-8 photoresist such as a photoinitiator and an inhibitor, as well as the intensity of the UV source 2.

Examples of SU-8 waveguides include a multi-mode interferometer (MMI) coupler, a Y-branch power splitter and a micro-ring resonator (MRR), are designed. The working principle of MMI power splitters is based on the self-image theory. For a 1×N MMI splitter, the length L_{MMI} of the core section is typically chosen as:

$${L}_{MMI} = 3 {L}_{π} / 4 N = 3 π / 4 N ( {β}_{0} - {β}_{1} ) , \qquad ( 2 )$$

where L_{π} is the beat length of the two lowest-order modes, N is the number of output waveguides, β₀ and β₁ are the propagation constants of the first and second order modes, respectively. The separation Wₛₚ between two output waveguides is:

$${W}_{sp} = ( W + ( \frac{λ}{π} ) {( \frac{1}{{n}_{r}} )}^{2 σ} {( {n}_{r}^{2} - {1}^{2} )}^{1 / 2} ) / N , \qquad ( 3 )$$

where W is the width of the MMI core, λ is wavelength, nᵣ is the refractive index of the SU-8 waveguide, σ=0 for TE mode and σ=1 for TM mode. In the present example, the width of the MMI core is chosen to be 40 μm to excite enough modes as well as to provide enough separation between two output waveguides. The eigenmode expansion propagation solver is utilized to optimize the MMI coupler. The other parameters of the MMI coupler include: a length of MMI is 774.2 μm, and a separation between two output waveguides is 20.1 μm.

The 1×2 Y-branch power splitter includes an input waveguide, two S-bends and two output waveguides. The radius of the S-bends is chosen to be 300 μm to attain small bending loss as well as to guarantee enough separation between the two output waveguides.

For the design of the MRR, an MMI-like gapless coupling section is introduced to achieve shorter coupling length and larger fabrication tolerance. Taking bending loss into consideration, the radius of the MRR is chosen to be 150 μm.

Other types of waveguides are contemplated as being applicable in the context of the present invention in different embodiments.

In experiments, the silicon wafer 606 capped with the 4-μm thick SiO₂ layer 604 was used as the substrate 16. Before spin coating of the SU-8 waveguide 40, an adhesion promoter was spun on the silicon wafer 46 at a speed of 3000 rpm for 30 sec to promote the adhesion between SU-8 and silica. Then the SU-8 waveguide 600 was spin-coated at a speed of 4000 rpm for 1 min. The thickness of the SU-8 layer was measured to be ˜2.1 μm. After soft baking at 65° C. for 5 min and 95° C. for 10 min, optical exposure was conducted under the light intensity of 61.91 mW/cm² to inscribe the designed patterns into the SU-8 waveguide 40. Then, samples were post-baked at 65° C. for 15 min and 95° ° C. for 30 min. After development in 1-Methoxy-2-propyl acetate for 2 min, the samples were finally hard-baked at 120° C. for 1 hour. A relatively low ramping rate, i.e., about 7.1° C./min, was applied to the heating up and cooling down processes in both post-bake and hard-bake. After the fabrication of waveguides, the substrate 16 after fabrication with optical waveguides or other photonic devices was cut on both sides for edge coupling. Two lensed fibers were used to couple light into and out of the waveguides.

It is known that the proximity effect in optical exposure will result in distortion of geometry and thereby lead to performance deterioration of a fabricated waveguide. To compensate for the proximity effect, the scattered light intensity distribution of each pixel of the light pattern is modeled by using a Gaussian-like distribution function:

$$P ( r ) = {P}_{0} {e}^{- 2.773 {r}^{2} / {w}^{2}} , \qquad ( 4 )$$

where P is the scattered light intensity of adjacent pixels with the distance of r to the central position of the light pixel with the peak intensity of P₀, and w is the full width at half maximum (FWHM) of the scattered light distribution. If it is assumed that each light pixel has the same scattered distribution, one can obtain the distribution of light intensity of all pixels of a pattern by superposing the light intensity of all adjacent pixels. With such a distribution, one can thus offset the intensity of the pixels whose intensity was increased due to the scattering of adjacent light pixels to compensate for the proximity effect.

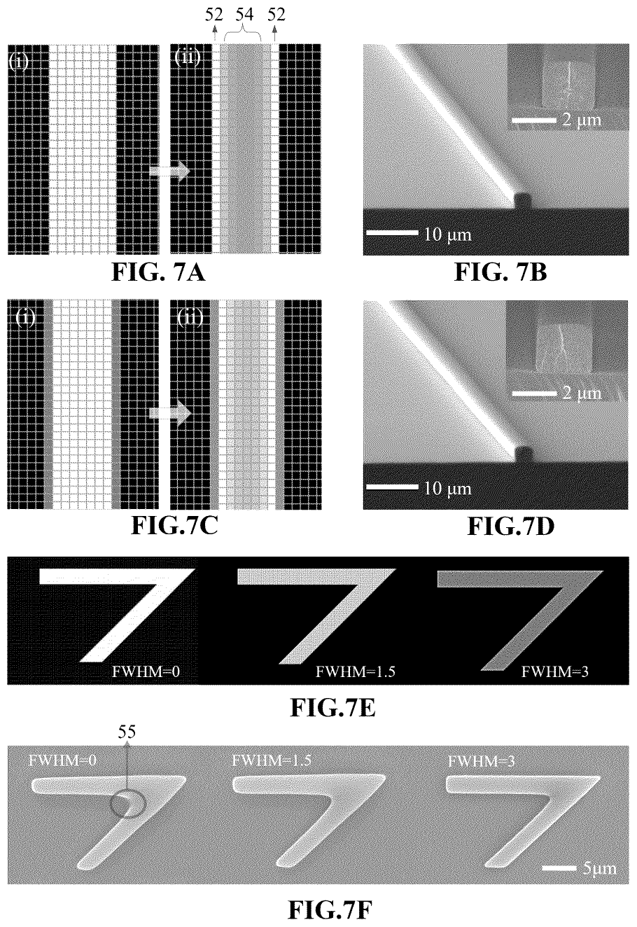

FIG. 7A(i) shows an example of a line pattern, which could be a short section of the optical waveguide 600, and FIG. 7A(ii) is its exposure dose-map for compensation of the proximity effect and nonlinear response curve of photoresist. It can be seen that pixels 52 at the edge of the waveguides 600 have a higher grayscale value while the pixels 54 in the middle of the waveguides 40 have a lower grayscale value because of heavier scattering of light.

To optimize not only the total exposure time t_{T} but also the threshold of exposure time to in Eq. (1) and the FWHM w in Eq. (4), a line pattern with a half-maximum gray edge, as shown in FIG. 7C, and an angled line pattern, as shown in FIG. 7E, have been designed for use in exposure tests. The line pattern is formed by the non-black pixels shown in FIGS. 7A, 7C and 7E.

FIG. 7A(ii) and FIG. 7C(ii) are exposure dose-maps that have been generated after taking into account both proximity effect compensation and nonlinear response curve of photoresist.

FIGS. 7B and 7D show scanning electron microscopy (SEM) images of fabricated line patterns using the exposure dose-maps in FIG. 7A(ii) and FIG. 7C(ii), respectively.

Here, the total exposure time t_{T}, the threshold time to and the FWHM w are 18 sec, 1.8 sec, and 3.0, respectively. It can be seen from FIGS. 7B and 7D that both of the all-white 8-pixel wide line pattern and 9-pixel wide line pattern with half-maximum gray edges can fabricate line waveguides with width of 2.4 μm after optimization of these parameters. FIG. 7E and FIG. 7F show the effects of a different full width at half maximum (FWHM) w on the exposure dose-maps and the fabricated patterns, respectively. From FIG. 7F, one can see that some residue caused by the proximity effect was observed in the inner corner 55 of the angled line pattern when the FWHM w is 0. A better geometry without obvious residue in the inner corner was achieved when the FWHM w is increased to 3.0, which means that the proximity effect has been well compensated. Notably, if the fabrication conditions, such as the chemical constituents, the thickness of the photoresist and the intensity of exposure UV light, are changed, these parameters including the total exposure time t_{T} and the threshold of exposure time to in Eq. (1) and the FWHM w in Eq. (4) need optimization again to fabricate a structure with a depressed proximity effect.

Although a DMD chip has millions of pixels, typically 1920×1080 pixels, the size of its optical image projected on the substrate 48 is about 572×322 μm² because of the use of reduction projection optics (composed of the relay optics 4 and objective lens 8). Therefore, the method is improved by stitching many sub-patterns in the fabrication of a practical waveguide device with input/output components. To reduce optical loss of stitching misalignment, transition zones are introduced between adjacent sub-patterns. The grayscale values, which correspond to the exposure doses, of the pixels in the transition zone in quadratic form so as to compensate for the potential width difference induced by two separated exposures. Specifically, for a transition zone defined by pixel position from x₀ to x₁, the gray values of the transition zone in two successive submaps are:

$$\{ \begin{matrix}{g}_{f} ( {x}_{l} ) = {g}_{0} ( {x}_{l} ) [ 1 - {x}_{l} + 4 c ( {x}_{l} - {x}_{l}^{2} ) ] , \\ {g}_{b} ( {x}_{l} ) = {g}_{0} ( {x}_{l} ) [ {x}_{l} + 4 c ( {x}_{l} - {x}_{l}^{2} ) ] ,\end{matrix} \qquad ( 5 )$$

where gₜ and g_{b} are modified grayscale values of the transition zone in the current and the adjacent submaps, respectively, g₀ is the original grayscale value of the designed pattern, the local pixel position x₁=(x−x₀)/(x₁−x₀), and c is a compensation coefficient.

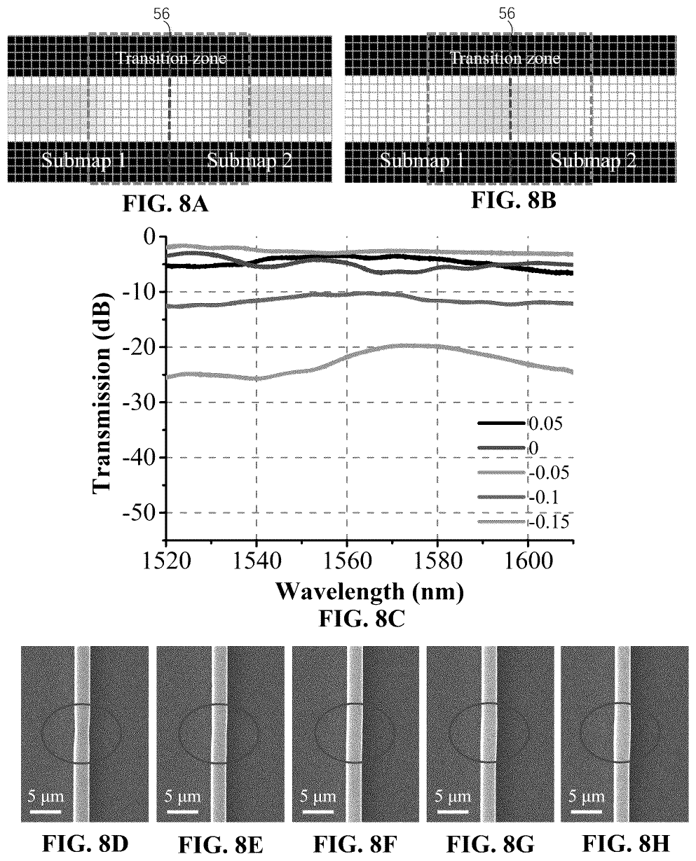

FIGS. 8A and 8B show grayscale images of the transition zone with the compensation coefficients of 0.1 and −0.1, respectively. When the compensation coefficient is positive, the grayscale value of the pixels around the center line is a little brighter, which means the compensation of a larger exposure dose (i.e., longer exposure time). When the compensation coefficient is negative, the grayscale value of the pixels around the abutting center line becomes smaller, which indicates a decrease of the exposure dose (i.e., shorter exposure time). Here, the max grayscale value has been normalized to 255 so as to create 8-bit exposure dose-maps for the grayscale exposure process. FIG. 8C shows the measured transmission spectra of the fabricated waveguides with the compensation coefficients of −0.15, −0.1, −0.05, 0, and 0.05, and the SEM images of their corresponding stitched transition zone are shown in FIGS. 8D-8H, respectively. Experimental results show that when the compensation coefficient is negative, the SU-8 waveguide 600 at the stitching region becomes thinner and the waveguide loss increases. When the compensation coefficient equals or is larger than 0.05, the SU-8 waveguide SU-8 600 at the stitching region becomes a bit wider and the waveguide loss also increases. When the compensation coefficient is between −0.05 and 0, there is no observable stitching trace and the loss of the fabricated SU-8 waveguide is relatively small. Notably, these optimal fabrication parameters depend on the configuration of the digital UV lithography exposure apparatus 100, such as the types of the UV source 2, the spatial light modulator 1, and the projection optics 4, as well as the chemical constituents and thickness of the SU-8 layer, which is the spin-coated SU-8 thin film before patterning. The optimization procedure described above is repeated to obtain new optimal parameters in case the configuration of the digital UV lithography exposure apparatus 100 or the SU-8 layer is altered as shown in FIGS. 7A-8F.

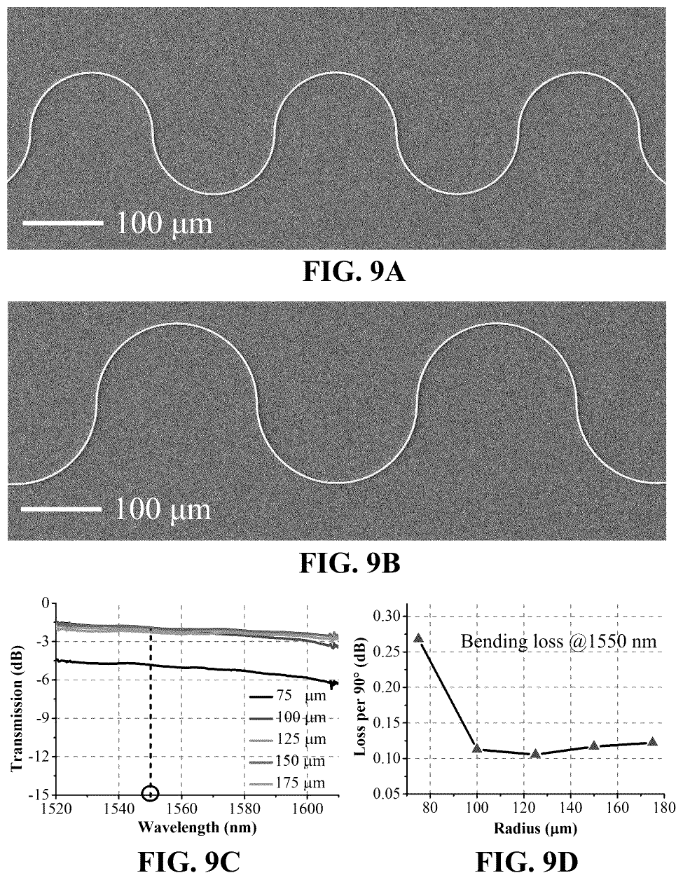

To determine an appropriate radius for bend waveguides such as MRRs, S-bends with different radii were fabricated. The height and width of the waveguides were kept to 2.1 μm and 2.4 μm, respectively. Each waveguide included eighteen 90°-arc waveguide sections with a fixed bending radius. FIGS. 9A and 9B show two examples of fabricated bend waveguides with radii of 75 μm and 100 μm, respectively. The measured transmission spectra of the bend waveguides with the radii of 75 μm, 100 μm, 125 μm, 150 μm, and 175 μm are given in FIG. 9C. The transmission spectra were normalized with respect to a straight waveguide with similar length so as to exclude the effects from coupling loss and propagation loss. FIG. 9D shows a normalized bending loss of each 90°-arc waveguide section at 1550 nm, which indicates that very low bending loss (˜0.1 dB/90°) can be achieved when the radius is larger than 100 μm, which is comparable to the result achieved by traditional photolithography.

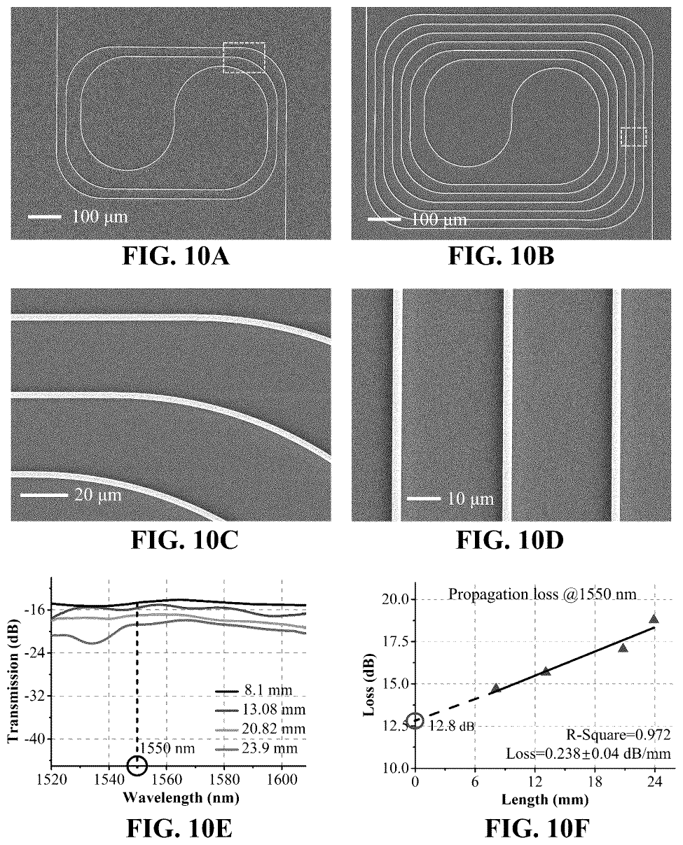

Therefore, the radius of bend waveguides, such as MRR or spiral waveguides, were chosen to be 150 μm so as to minimize bending loss in experiments. FIGS. 10A and 10B are scanning electron microscope (SEM) images of the fabricated spiral waveguides with different lengths, and FIGS. 10C and 10D are enlarged images of the boxed areas in FIGS. 10A and 10B, respectively. FIG. 10E shows the measured transmission spectra of waveguides with the lengths of 8.1 mm, 13.1 mm, 20.8 mm, and 23.9 mm, respectively. FIG. 10F shows the measured losses at a wavelength of 1550 nm, which was extracted from FIG. 10E. There are little ripples in the measured transmission spectra, which could be induced by the surface reflections between the lensed optical fiber and the fabricated waveguide or the reflections between micro-particles introduced during the fabrication process. The relative position, the light reflection path between the optical fiber and the waveguide facet are a little different for different measurements, and the light reflection path between different particles are also different, and therefore these small spectral peaks or ripples appear at different wavelengths. One can see that the measured loss linearly increased with the length of the waveguide, from which the propagation loss can be deduced to be ˜0.238 dB/mm at the wavelength of 1550 nm. The loss besides transmission loss, such as edge coupling loss, was 12.8 dB, which was calculated by setting the SU-8 waveguide 600 length to 0 in the fitted linear regression line. The propagation loss of the present fabricated waveguide SU-8 40 is comparable with the SU-8 waveguides fabricated by using standard lithography processes. The main cause of such a high propagation loss is the scattering loss induced by tiny particles or impurities attaching on or mixed within waveguides, since the exposure processes were not conducted in the clean room, but not the sidewall roughness. The optical resolution of the DUL apparatus 100 is about 298 nm. Therefore, to fabricate waveguides with a width of 2.4 μm, the designed patterns of waveguides have a width of 8 pixels, which are sufficient to produce a smooth boundary by an 8-bit grayscale exposure technique.

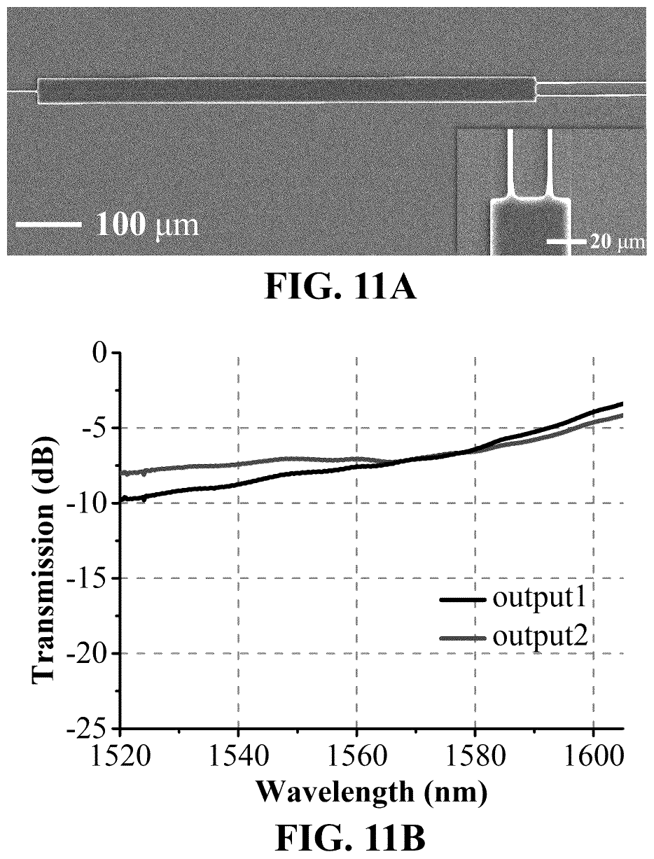

Different waveguide components were fabricated and demonstrated to verify the performance of the DUL apparatus 100 on the fabrication of SU-8 waveguides. Two kinds of power splitters, i.e., the MMI coupler and the Y-branch, were fabricated, wherein FIG. 11A shows the SEM image of the fabricated MMI coupler. The measured normalized transmission spectra from its two output ports are given in FIG. 11B. It can be seen that the symmetrical MMI power splitter can split light power uniformly in a broad range of wavelength from 1520 nm to 1610 nm and the power variations of the transmission spectra are 6.5 dB and 4.0 dB, respectively. The excess loss of the fabricated MMI coupler is mainly induced by the scattering at the junctions between the MMI core region and the access waveguides.

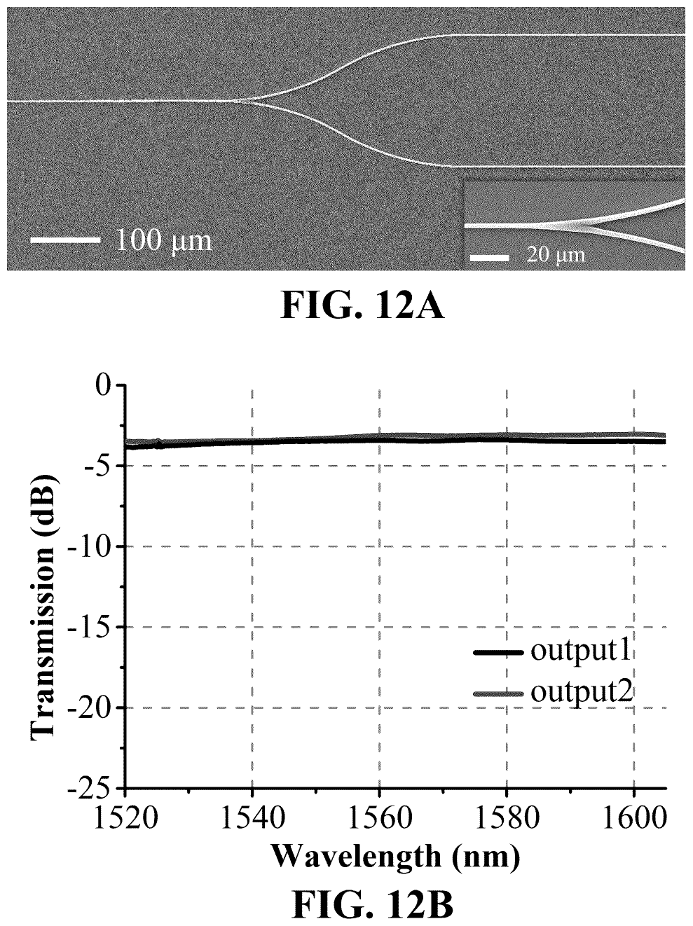

FIG. 12A is the SEM image of a fabricated 1×2 Y-branch power splitter, which has one access waveguide and two branching waveguides with S-bends. The radius of the S-bends was chosen to be 300 μm to minimize bending loss as well as provide enough separations between two branching waveguides. The inset in FIG. 12A shows the enlarged view of the Y-branch junction. FIG. 12B shows the measured normalized transmission spectra of the Y-branch power splitter. The spectra measured from the two output ports are close to each other and do not depend very much on the waveguide within the range of measured wavelengths. Their output power difference at 1550 nm is 0.15 dB, and it does not exceed 0.36 dB over the wavelength from 1520 nm to 1610 nm.

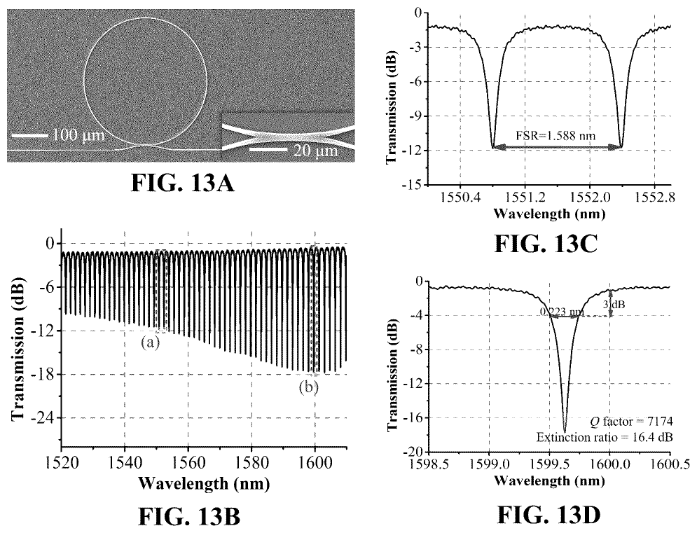

An MRR with a gapless coupling section was also fabricated as shown in FIG. 13A. The radius of the ring of the MRR was chosen to be 150 μm. FIG. 13B shows the measured transmission spectrum of the MRR at a wavelength ranging from 1520 nm to 1610 nm. FIGS. 13C and 13D are the close-ups of the spectra at the wavelengths near 1551 nm and 1600 nm, respectively. From FIG. 13C, it can be seen that the free spectral range (FSR) near 1551 nm is about 1.588 nm, which is close to the simulated value of 1.575 nm. The highest quality (Q) factor corresponding to the transmission dip at the wavelength of 1600 nm is 7174, and its extinction ratio is 16.4 dB.

In summary, the above discloses the design, fabrication, and characterization of SU-8 waveguides by using a new fabrication process with a DMD-based DUL apparatus. The embodiments of the new methods and systems can not only overcome the shortage in flexibility of traditional optical lithography, but also render a significantly higher productivity output than E-beam lithography and laser direct writing technologies. An exposure dose-map has been introduced through a numerical pre-estimation of the light scattering effect to compensate the proximity effect induced by light scattering in the SU-8 waveguide 600 so as to depress lithography resolution degradation. A method has been established to correct the exposure dose-map and thereby make it adaptive to the nonlinear response curve of photoresist. Moreover, a strategy based on a grayscale exposure method has also been demonstrated to seamlessly stitch patterns to produce large-area high-quality waveguide devices.

Experiments have demonstrated that a bending loss of a fabricated waveguide is about 0.1 dB/90°-arc when the bending radius is not smaller than 100 μm. The propagation loss is 0.238 dB/mm at the wavelength of 1550 nm. Moreover, the fabricated MMI and Y-branch power splitters can uniformly split input power at a broad range of wavelength from 1520 nm to 1610 nm. The fabricated MRR has a Q-factor over 7100 and an extinction ratio of about 16 dB.

Such a grayscale and dynamic optical exposure technology is very advantageous in fabricating waveguides with 2.5D and even 3D structures, such as Maxwell fisheye-based multimode crossings. After integrating with machine vision technology, this technology can be further developed in the field of intelligent adaptive lithography technology for development of novel waveguide devices and biosensors.

A digital camera-based machine vision module has been integrated to the system to enable the precise checking of the substrate tilt angle and automatic correction of z-position deviation for high-resolution exposure. It can be further improved to develop a closed-loop dynamic exposure method that is adaptive to the substrate condition and instant photoresist response towards the development of intelligent lithography system.

Although a few embodiments of the present invention have been shown and described, it would be appreciated by those skilled in the art that changes may be made in this embodiment without departing from the principles and spirit of the invention, the scope of which is defined in the claims and their equivalents.

What is claimed is:

1. A method of performing digital lithography for a maskless optical exposure process, comprising:
converting a computer aided design (CAD) pattern into a bitmap; and
transforming the bitmap to an exposure dose-map for (1) compensation of a proximity effect and (2) adaptive to a non-linear response curve of a photoresist, and
slicing the exposure dose-map into a plurality of submaps with transition zones around a boundary between two adjacent submaps so as to depress a stitching error caused by mechanical mispositioning when the substrate is moved from one position to the next by a motorized stage.

2. The method according to claim 1, further comprising:
performing a closed-loop exposure of the plurality of exposure dose-submaps on a substrate using a submap data bank generated by the transforming of the bitmap to the exposure dose-map and the slicing of the exposure dose-map into the plurality of submaps.

3. The method according to claim 1, where assuming that a gray value g is analogically represented by a depth of light penetration in the photoresist in the exposure process, a exposure time t is determined in accordance with the Beer Lambert law as
$$t = {t}_{0} exp ( g / {c}_{r} ) r$$
where t₀ is the threshold of exposure time, the constant cᵣ depends on contents of the SU-8 photoresist which is one of a photoinitiator or an inhibitor, as well as an intensity of a UV source which generates UV light to provide a light pattern.

4. The method according to claim 1, wherein the compensation of the proximity effect comprises:
modeling a scattered light intensity distribution of each pixel of a light pattern derived from the CAD pattern using a Gaussian-like distribution function.

5. The method according to claim 4, wherein the Gaussian-like distribution function is:
$$P ( r ) = {P}_{0} {e}^{- 2.773 {r}^{2} / {w}^{2}} ,$$
where P is a scattered light intensity of adjacent pixels of the light pattern with a distance of r to the central position of the light pixel with a peak intensity of P₀, and w is a full width at half maximum (FWHM) of the scattered light distribution.

6. The method according to claim 1, wherein grayscale values corresponding to exposure doses of the pixels in each transition zone are compensated in quadratic form so as to compensate for the potential width difference induced by two separated exposures.

7. The method according to claim 6, wherein each transition zone is defined by pixel position from x₀ to x₁, and gray values of the transition zone in two successive submaps are:
$$\{ \begin{matrix}{g}_{f} ( {x}_{l} ) = {g}_{0} ( {x}_{l} ) [ 1 - {x}_{l} + 4 c ( {x}_{l} - {x}_{l}^{2} ) ] , \\ {g}_{b} ( {x}_{l} ) = {g}_{0} ( {x}_{l} ) [ {x}_{l} + 4 c ( {x}_{l} - {x}_{l}^{2} ) ] .\end{matrix}$$

8. A method of performing the optimization of parameters for DUL process, comprising:
designing a line pattern with all white pixels;
designing a line pattern with half-maximum gray edges on both sides and one more pixel wider in line width than the abovementioned line pattern; and
designing one angled line pattern;
to optimize a total exposure time t_{T}, a threshold of exposure time t₀, and an FWHM w via trial fabrication and optimization of all the three patterns.

9. A digital ultraviolet lithography (DUL) apparatus comprising:
a spatial light modulator comprising a plurality of pixels used as a virtual mask;
a processor configured to:
convert a computer aided design (CAD) pattern into a bitmap;
transform the bitmap to an exposure dose-map for (1) compensation of a proximity effect and (2) adaptive to a non-linear response curve of a photoresist, and
divide the exposure dose-map into a plurality of submaps with transition zones around a boundary between two adjacent submaps so as to depress a stitching error caused by mechanical mispositioning;
wherein the spatial light modulator is configured to generate a light pattern to expose the photoresist on a substrate using the plurality of submaps one by one.

10. The DUL apparatus according to claim 9, further comprising:
a camera-based machine vision module to check a plurality of markers on the substrate for position checking; and
inspect the levelness of the substrate,
wherein the spatial light modulator creates a structured light pattern to increase accuracy of position checking and levelness inspection.

11. The DUL apparatus according to claim 9, further comprising:
a camera-based machine vision module to monitor the evolution of a photoresist that can instantly respond to UV exposure and thereby develop a closed-loop exposure scheme that is self-adaptive to instant response of photoresist;
precisely locate the target position of a substrate for overlay exposure process; and
precisely locate a small target position of a substrate or part of a structure for in-situ lithography process.
